(19) United States
(12) Patent Application Publication
(10) Pub. No.: US 2007/0040605 A1
(43) Pub. Date: Feb. 22, 2007

(54) Shared receiver and transmitter filter

(75) Inventors: Yiping Fan, Fremont, CA (US); Chang-Yu Wang, Taipei City (TW); Hongyu Li, Cupertino, CA (US); Chieh-Yuan Chao, Fremont, CA (US)

Correspondence Address: Daniel R. McClure;THOMAS, KAYDEN, HORSTEMEYER & RISLEY, L.L.P., Suite 1750, 100 Galleria Parkway, Atlanta, GA, 30339, US

(73) Assignee: Hyperband Communications, Inc.

(21) Appl. No.: 11/209,912

(22) Filed: Aug. 22, 2005

(51) Int. Cl. H03K 5/00

(52) U.S. Cl. 327/554

(57) ABSTRACT

The present invention provides methods and apparatuses for a shared filter transceiving system. A shared filter transceiving system having a capacitor bank to adjust the time constant of the shared filter comprises a first input configured to receive a first signal. The capacitor bank is coupled to the first input having a plurality of selectable capacitors including a reference capacitor. A second input is coupled to the capacitor bank configured to receive a second signal. A configurable switch is coupled to the capacitor bank configured to couple a first selectable capacitor with the reference capacitor when the first input is active and couple a second selectable capacitor with the second reference capacitor when the second input is active. The second selectable capacitor is a predetermined offset value of the first selectable capacitor.

### FIELD

The present invention relates to filters for communication systems and, more particularly, to methods and apparatuses for a shared receiver and transmitter filter system.

### BACKGROUND

Filter design plays a very important role in communication systems. Ideally, a receiver channel filter passes the desired signal with minimum signal distortion, maximize signal to noise ratio, rejects out of band interferences, and limits the noise bandwidth to a satisfactory level. Unfortunately, the goal of having less distortion conflicts with the design goal of providing more rejection of noise and interference. Therefore, the receiver filter is often designed with a number of trade-offs.

On the other hand, a transmitter filter is designed to limit or shape the transmitted signal bandwidth within a particular transmitted spectrum in order to satisfy regulations and/or standards. Since a transmitted signal for digital communications is typically generated by digital to analog converter, the design of the transmitter filter should be capable of removing the harmonics created by the sample and hold operation of the digital to analog converter. The harmonic rejection requirement in the design of the transmitter filter depends on the characteristics of the digital to analog converters such as the sampling rate. The transmit filter is often called a reconstruction filter, since the transmit filter reconstructs the analog waveform from the output of the digital to analog converter which looks like a stair case waveform.

Often, the single most important filter design parameter is the filter bandwidth. In a typical communication system, the transmitter filter will usually have a wider bandwidth than that of the receiver filter. Accordingly, in order to optimize the performance of receiver filters and transmitter filters, many current transceiver designs use separate transmit and receive filters. However, separate transmit and receive filters adds redundancy, needs more switching time between transmit and receive, increases the size of the transceiver, and cost to manufacturing.

Accordingly, it is desirable to provide a transceiver filter design that overcomes the disadvantages of current separate transmit and receiver filter designs. What is needed is a method and apparatus that combine the transmit and receiver filters

### SUMMARY OF THE INVENTION

The present invention discloses methods and apparatuses for a shared filter transceiver and more particularly the shared filter is used in Time Division Multiple Access (TDMA) systems where the communication device does not transmit and receive at the same time. The shared filter transceiver is based on using a single filter that is calibrated for receive and transmit. Accordingly, an embodiment of the present invention discloses a shared filter apparatus having a capacitor bank to adjust the time constant of the shared filter comprising the capacitor bank having a plurality of selectable capacitors. A configurable switch is coupled to the capacitor bank configured to couple a first selectable capacitor of the capacitor bank in a first direction and to couple a second selectable capacitor of the capacitor bank in a second direction.

In accordance with another aspect of the present invention, the capacitor bank includes a reference capacitor selectively coupled to the first selected capacitor and the second selected capacitor.

In accordance with another aspect of the present invention, the first direction is a receive direction and the second direction is a transmit direction.

In accordance to another embodiment of the present invention, a calibration circuit is coupled to the configurable switch configured to measure a time constant of the reference capacitor.

In accordance to yet another embodiment of the present invention, the calibration circuit selects the first selectable capacitor in response to the time constant measurement of the reference capacitor.

In accordance with another aspect of the present invention, the calibration circuit selects the second selectable capacitor based upon an offset value of the first selectable capacitor. Since calibration performed with the reference capacitor compensates for any PTV variation in selection of the first selectable capacitor, the second selectable capacitor is based upon an offset value of the first selectable capacitor without performing calibration to determine the second selectable capacitor which saves time and resources.

In accordance with yet another aspect of the present invention, the first selectable capacitor and the reference capacitor produces a first predetermined time constant and the second selectable capacitor and the reference capacitor produces a second predetermined time constant.

Other aspects and advantages of the present invention will become apparent to those skilled in the art from reading the following detailed description when taken in conjunction with the accompanying drawings.

### BRIEF DESCRIPTION OF THE DRAWINGS

FIG. 1 illustrates a graph of receive and transmit filter response;

FIG. 2 illustrates a transceiver with separate receive and transmit filters;

FIG. 3 illustrates a transceiver with shared receive and transmit filters in accordance with an embodiment of the present invention;

FIG. 4 illustrates a graph of filter bandwidth variation due to process, temperature and supply voltage variation;

FIG. 5 illustrates an example circuit diagram for filter bandwidth compensation;

FIG. 6 illustrates an example circuit diagram for time constant measurement;

FIG. 7 illustrates an example implementation for filter bandwidth coverage;

FIG. 8 illustrates an example graph of the response of the RX filter and TX filter when there is no PTV variation;

FIG. 9 illustrates an example graph of the response of the RX filter and TX filter when response is reduced by 1 MHz due to PTV variation; and

FIG. 10 illustrates an example graph of the response of the RX filter and TX filter when response is increased by 1 MHz due to PTV variation.

### DETAILED DESCRIPTION

As disclosed below, the present invention provides methods and apparatuses for a shared filter. In general, this invention provides a single filter serving for both transmit and receive with two different calibrated filter bandwidths. According to an embodiment of the present invention, a shared filter serving a receive or transmit function with a first calibrated filter bandwidth that is different from serving a transmit or receive function with a second calibrated bandwidth is used for time division multiple access (TDMA) communication systems. Typical examples of a TDMA communication system are wireless local area network (WLAN) such as IEEE 802.11 standard. In these kinds of systems, since receive and transmit functions do not occur at the same time, sharing one filter which has a different bandwidth for receiving and transmitting can be accomplished.

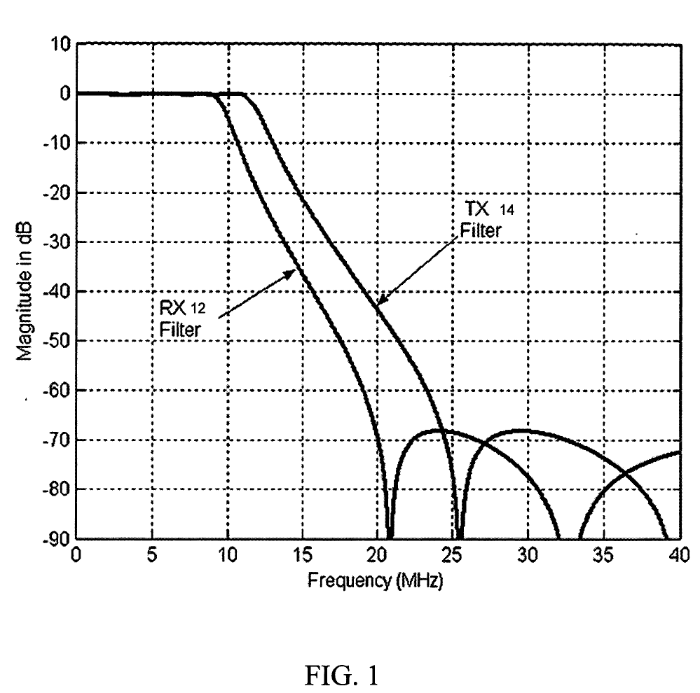

FIG. 1 is a graph showing different frequency responses for a receive filter and a transmit filter. Both receive and transmit filters are 5^{th} order Elliptical filter with 9 MHz bandwidth for the receiver filter curve 12, and 11 MHz bandwidth for the transmitter filter curve 14.

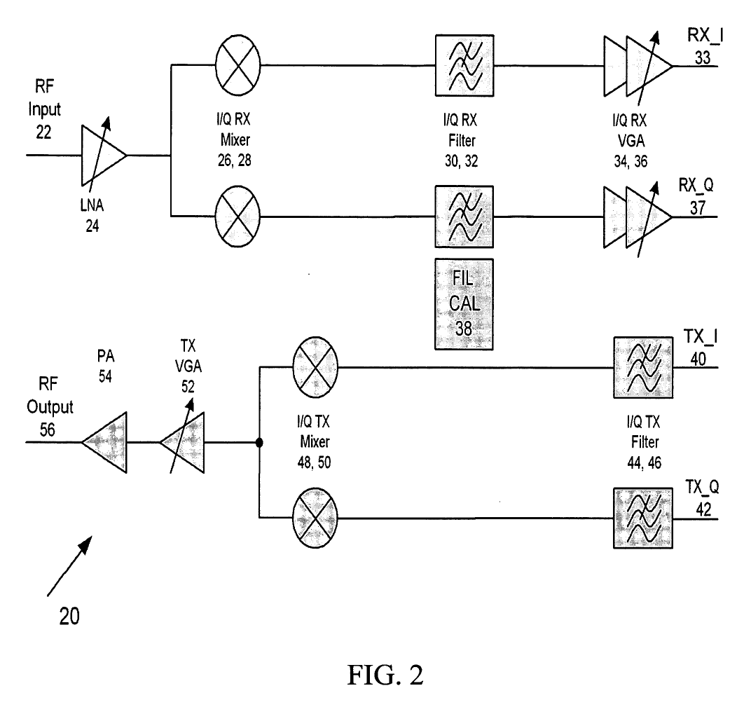

FIG. 2 shows an example of a simplified zero intermediate frequency (ZIF) transceiver architecture 20 which uses separate receive and transmit filters. An RF input 22 is received by a low noise amplifier (LNA) 24. In-phase and quadrature (I&Q) mixers 26 and 28 provide inputs to the I&Q receive filters 30 and 32. I&Q variable gain amplifiers 34 and 36 amplifies the in-phase and quadrature signals to provide RX_I 33 and RX_Q 37. FIL CAL 38 is a filter calibration circuit to tune the time constant for the filters. For transmission of an RF signal, input TX_I 40 and TX_I 42 are applied to in-phase and quadrature (I&Q) filters 44 and 46. In-phase and quadrature (I&Q) TX mixers 48 and 50 receive the in-phase and quadrature signals from the I&Q filters 44 and 46 and applies a combined signal to TX variable gain amplifier (VGA) 52 which outputs to power amplifier (PA) 54 for transmission of an RF output 56.

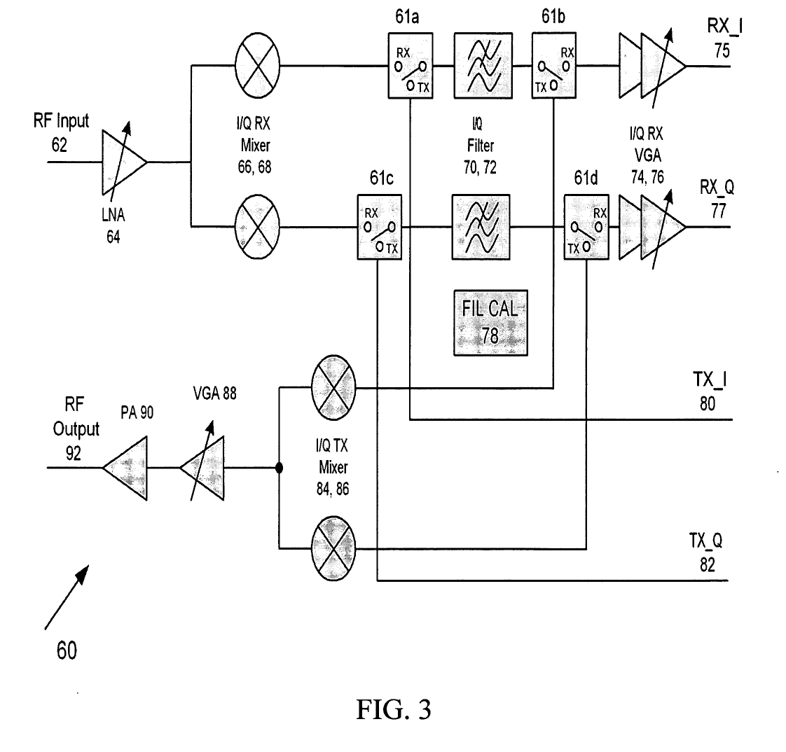

According to an embodiment of the present invention, FIG. 3 depicts a ZIF architecture where the receive filter and transmit filter is shared. In the receive mode switches 61a, 61b, 61c, and 61d are selected for signal flowing in a first direction. An RF input 62 is received by a low noise amplifier (LNA) 64. In-phase and quadrature (I&Q) mixers 66 and 68 provide inputs to shared I&Q filters 70 and 72 through switches 61a and 61c. I&Q variable gain amplifiers 74 and 76 amplifies the in-phase and quadrature signals which flow through switches 61b and 61d to provide RX_I 75 and RX_Q 77. FIL CAL 78 is a filter calibration circuit to tune the time constant for the filters. For transmission of an RF signal with signal flowing in a second direction, switches 61a, 61b, 61c, and 61d are selected for the second direction. Input TX_I 80 and TX_Q 82 are applied to the shared I&Q filters 70 and 72 through switches 61a and 61c. In-phase and quadrature (I&Q) TX mixers 84 and 86 receive the in-phase and quadrature signals which flow through switches 61b, 61d from the shared I&Q filters 70 and 72 and applies a combined signal to TX variable gain amplifier (VGA) 88 which outputs to power amplifier (PA) 90 for transmission of an RF output 92. In the exemplary embodiment, the transmit and receive directions are controlled by the four switches with one digital control signal (not shown) to turn the switches in the receive or transmit mode. Those skilled in the art will appreciate that there are many switch implementations which may be used to accomplish the switching in the two directions and that the exemplary switches merely demonstrate the switch concept.

Advantages of filter sharing include reduction in die size and cost, eliminate or substantially reduce filter settling time when the ZIF transceiver changes from receiving mode to transmitting mode and vise versa. Since the shared filter has powered applied in either mode, the toggling of modes between receive and transmit and vice versa is performed much faster as the settling time for the shared filter is substantially faster as compared to the separate filter architecture.

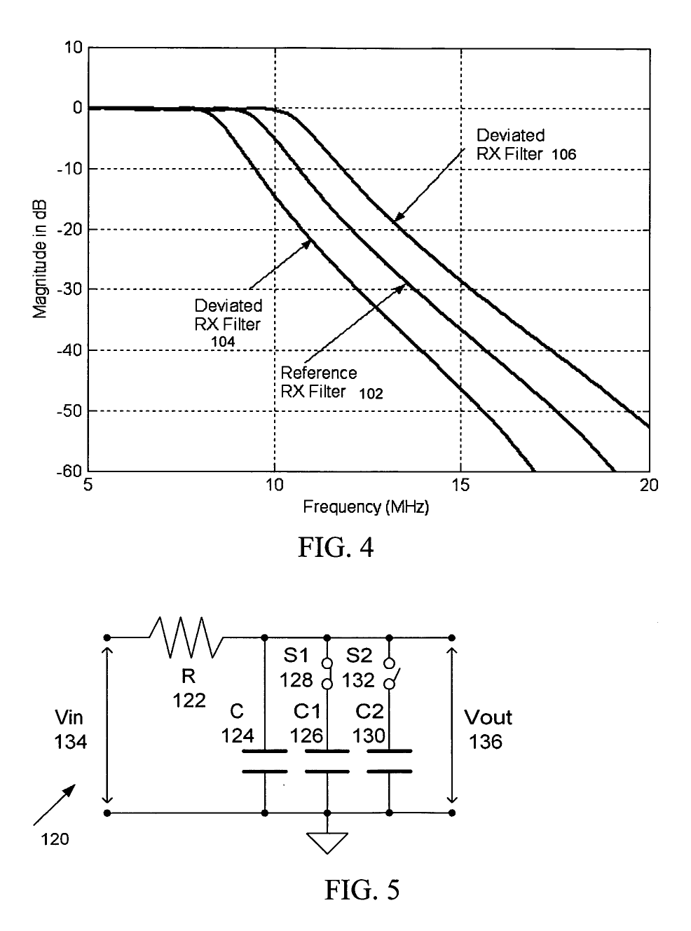

Since semiconductor manufacturing process varies from ideal, a filter bandwidth calibration is often performed for integrated filters in order to compensate for process, temperature and supply voltage variations (PTV). FIG. 4 shows graph 100 an example of the bandwidth change when there is PTV. The horizontal axis represents frequency in megahertz and the vertical axis represents magnitude in dB. The middle curve 102 represents the desired or reference filter response while the left curve 104 to the left of middle curve 102 has a reduced bandwidth and the right curve 106 to the right of middle curve 102 has an increased bandwidth.

Those skilled in the art will readily appreciate that the basic elements of active filter designs are operational amplifiers, resistors and capacitors. Time constant which is the multiplication of resistance and capacitance determines the bandwidth of a filter. The smaller the time constant, the wider is the filter bandwidth. According to one embodiment of the present invention, to properly calibrate a filter due to PTV variation, it is desirable to know how much the time constant has deviated from the desired levels. Once known, adjustment to the time constant can be applied though a change in the resistor or capacitor value. Since most modem circuits involve integrated circuits, compensation capacitors are commonly used to compensate for the time constant deviation because changing capacitors do not alter filter gain while changing resistors do affect the gain. Typically, capacitor banks having a plurality of capacitors within a range of values are formed on the integrated circuit. Capacitor selection circuitry select particular capacitors within the capacitor bank to fine tune the time constant to compensate for the time constant deviation. Those skilled in the art will readily understand the implementation of capacitor banks and the circuitry for the selection of capacitors within the capacitor banks. Accordingly, a detailed discussion on the process of selecting capacitors is not provided.

FIG. 5 shows a simple two level compensation circuit 120. The compensation circuit 120 includes an R resistor 122, reference or target C capacitor 124, C1 capacitor 126 coupled to S1 switch 128, and C2 capacitor 130 coupled to S2 switch 132. When a voltage Vin 134 is applied to the compensation circuit 120, there is a time delay before substantially the same voltage is received at Vout 136. The time delay is inverse proportional to the filter bandwidth and is used adjust the bandwidth of a filter. In default mode, S1 switch 128 is closed and S2 switch 132 is open. If the filter bandwidth of the filter is within the predetermined specification, no action is taken. With reference to FIG. 4, the filter response coincides with the middle curve 102. If the filter bandwidth is larger than that of the reference curve 102, then S2 switch 132 is closed. Accordingly, the filter response is shifted from the right curve 106 towards the middle curve 102 of FIG. 4. On the other hand, if the bandwidth is smaller, then S1 switch 128 is opened. Accordingly, the filter response is shifted from the left curve 104 towards the middle curve 102 of FIG. 4. Actual implementation of a compensation circuit often involves a complicated capacitor switch network coupled to a capacitor bank that is designed to provide precise compensation levels with fine granulites.

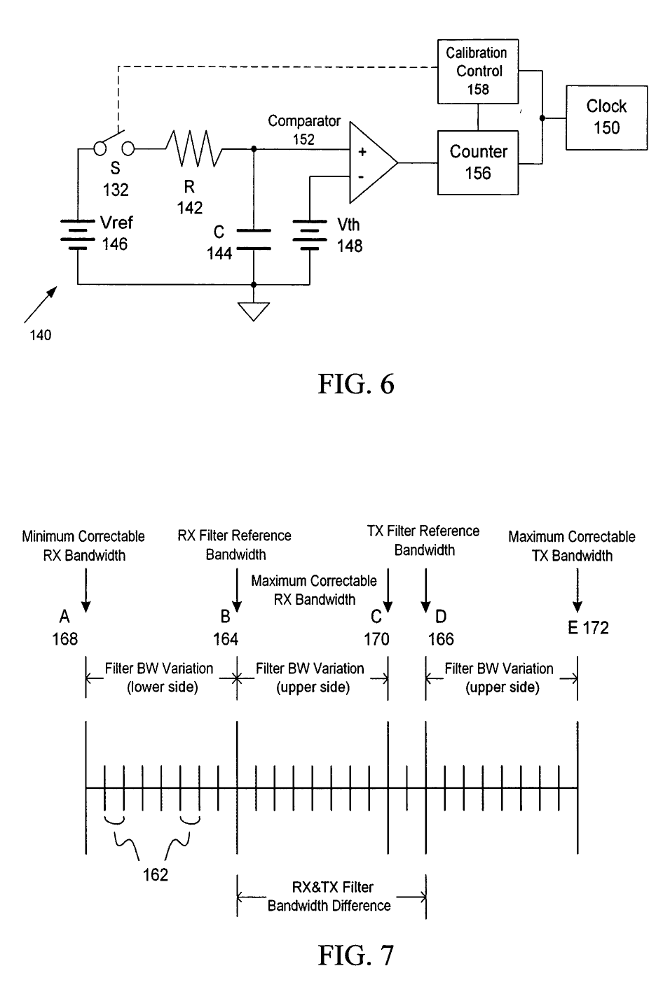

Before compensation may be applied, time constant for the reference or target configuration is measured to determine the magnitude of the variation from a predetermined reference. FIG. 6 shows an example time constant measurement circuit 140 that measures the time constant of the reference resistor R 142 and capacitor C 144. The time constant measurement circuit 140 consists of an RC circuit (R 142 and C 144), an accurate voltage source (Vref) 146, a threshold voltage (Vth) 148, an accurate clock, a S switch 152, a comparator 154, a counter 156, and calibration control 158. Initially, the capacitor C 144 is completely discharged. To begin calibration, the calibration control 158 activates S switch 152 which closes the switch 152. The voltage source 146 begins to charge the capacitor C 144 and the counter 156 begins to keep count. When the voltage across the capacitor C 144 exceeds a comparison voltage set by the Vth 148, the output of the comparator 152 changes from a logic 0 to a logic 1. The logic 1 output of the comparator 152 stops the counter 156 at a particular counter value. The counter value is proportional to the time constant. Based on the reading of the counter value, a difference between the reference time constant value and the actual time constant value is determined. The difference is then used to switch on or off capacitors to make the actual response close to the predetermined reference filter response.

According to another embodiment of the present invention, the reference filter bandwidth may not be optimal for different applications or the same application but with a different performance emphasis. Therefore, a changeable filter bandwidth is desirable with filter calibration. One effective approach is as follows:

Calibrate the reference filter and get the values for the capacitor switch value;

offset the capacitor switch value by adding or subtracting a number to obtain an optimal setting for a different application or different performance emphasis; and

the resulting switch value is the capacitor switch value with the offset filter bandwidth.

The advantage with the offset approach is the option to calibrate the filter to the reference bandwidth without an offset or to an offset reference bandwidth for a particular performance emphasis when an offset is desired. Since the reference filter bandwidth compensates the PTV variation after the filter calibration, the offset filter bandwidth also tracks PTV variation.

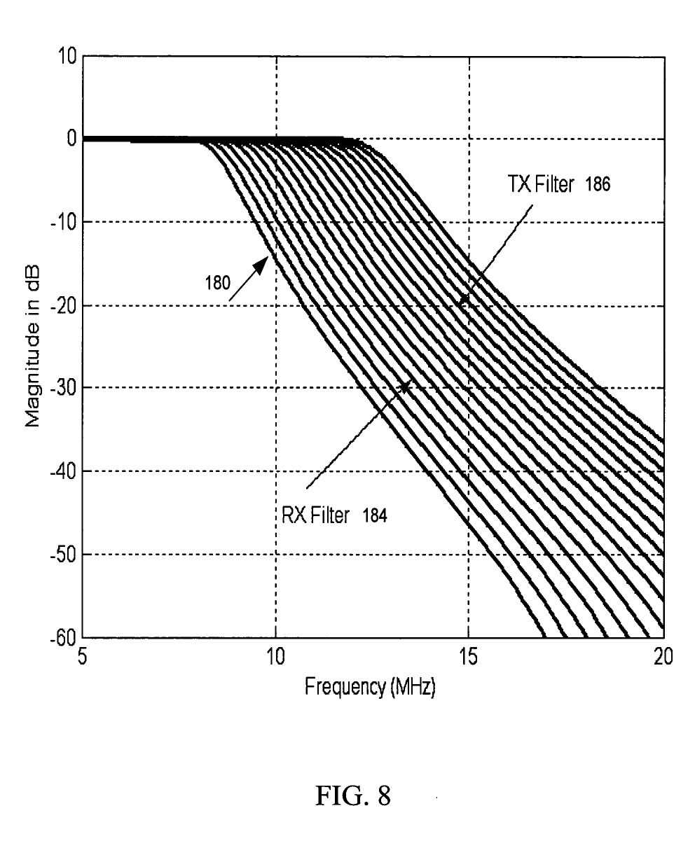

In accordance with an embodiment of the present invention, FIG. 7 illustrates a diagram for a shared filter bandwidth coverage. Each increment 162 represents a resolution of a bandwidth change in the selection of a particular capacitor in a capacitor bank (not shown). In the present example, the receive filter has a reference bandwidth at Point B 164 and the transmit filter has a reference bandwidth at Point D 166. From Point B 164 to Point A 168 is the range for filter bandwidth variation for narrower bandwidth while from Point B 164 to Point C 170 is the range for filter bandwidth variation for wider bandwidth. Since the transmit filter bandwidth is an offset from the receive filter bandwidth, Point D 166 to Point E 172 covers the same range as Point B 164 to Point C 170. Advantageously, the shared filter has a filter bandwidth from Point A 168 to Point E 172 when there is no PTV variation.

FIG. 8 is an example of the shared filter response when there is no PTV variation. In this example, the receive filter bandwidth is 9 MHz and the transmit filter bandwidth is 11 MHz. The filter bandwidth resolution is 250 kHz and the filter calibration will covers a +/− 1 MHz bandwidth variation. The leftmost curve 180 corresponds to Point A 168 of FIG. 7, and the rightmost curve 182 corresponds to Point E 172 of FIG. 7. The fifth curve from the left RX Filter 184 represents receive default setting and is the receive filter response. The fifth curve from the right TX Filter 186 represents transmit default setting and is the transmit filter response. Since there is no PTV variation for this case, the filter response remains the same before and after filter calibration.

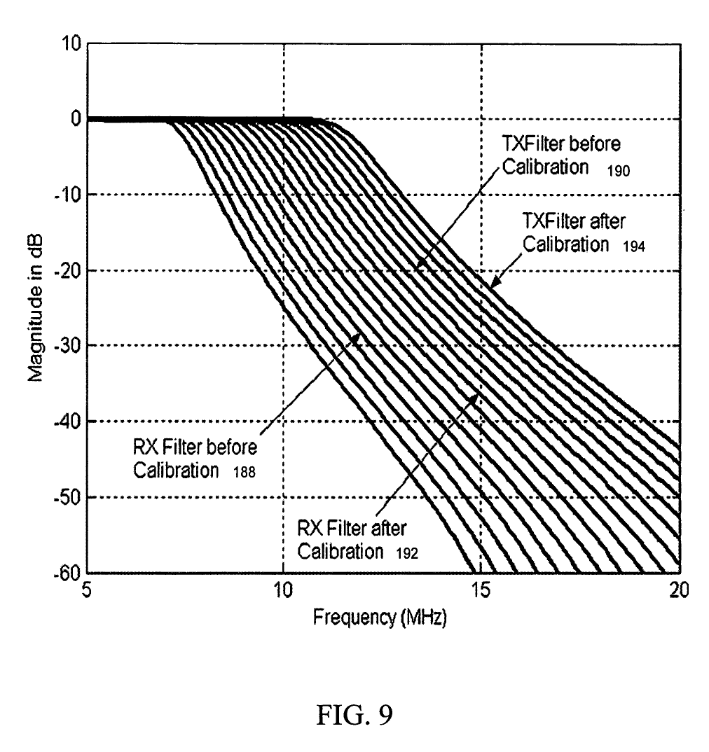

FIG. 9 represents another example graph of the shared filter response. In this case, there is PTV variation where the receive filter bandwidth is reduced by 1 MHz. RX Filter before Calibration curve 188 and TX Filter before Calibration curve 190 correspond to RX Filter curve 184 and TX Filter 186 of FIG. 8 but shifted to left by 1 MHz. After calibration, RX Filter after Calibration curve 192 and TX Filter after Calibration curve 194 are shifted by 1 MHz to the desired value. Accordingly, both the receive filter bandwidth and the transmit filter bandwidth are increased by 1 MHz and are properly compensated.

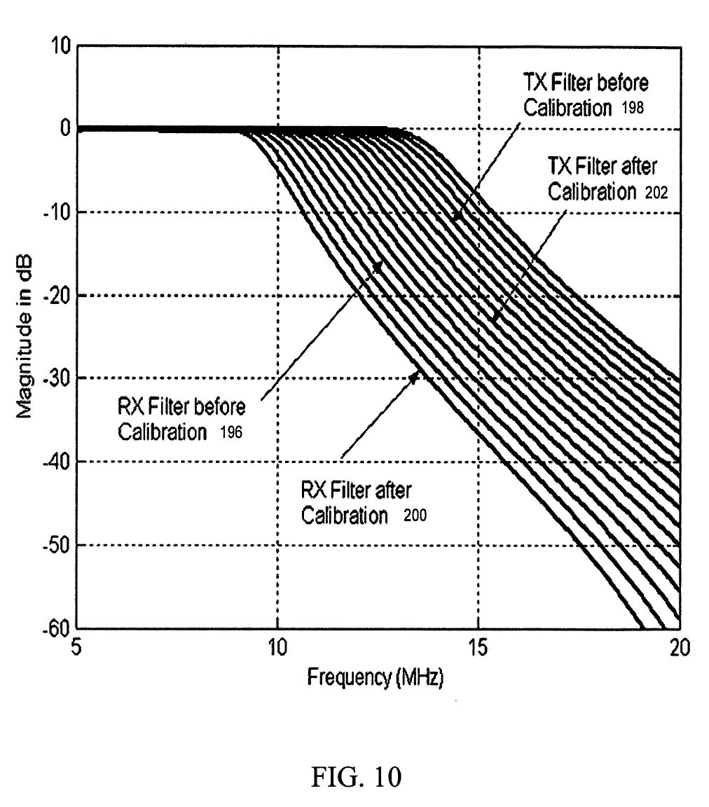

FIG. 10 shows an example graph of the shared filter response when the filter bandwidth is increased by 1 MHz due to PTV variation. RX Filter before Calibration curve 196 and TX Filter before Calibration curve 198 are shifted to the right by 1 MHz. After calibration, RX Filter after Calibration curve 200 and TX Filter after Calibration curve 202 are shifted by 1 MHz to the desired value. Accordingly, both the receive filter bandwidth and the transmit filter bandwidth are decreased by 1 MHz and are properly compensated.

Referring to FIG. 7, an advantage of the shared filter bandwidth coverage is that it is possible to switch Point B 164 with Point D 166 so that the new receive filter has a wider bandwidth or that the difference from Point D 166 to Point E 177 does not have to be the same as from Point B 164 to Point C 170. Accordingly, the shared filter bandwidth coverage provides built-in flexibility for a wide range of filter settings which save space, costs, and redundant circuitry in the manufacturing of integrated circuits.

While the foregoing detailed description has described several embodiments of the present invention, it is to be understood that the above description is illustrative only and not limiting of the disclosed invention. Obviously, many modifications and variations will be apparent to those skilled in the art without departing from the spirit of the invention.

We claim:

1. A shared filter apparatus having a capacitor bank to adjust the time constant of the shared filter, comprising:
a resister;
a capacitor bank having a plurality of selectable capacitors for adjusting the time constant of the shared filter, the capacitor bank coupled to the resister; and
a configurable switch coupled to the capacitor bank configured to couple one or more of the selectable capacitors of the capacitor bank in a first direction and to couple a second selectable capacitor of the capacitor bank in a second direction.

2. The shared filter apparatus of claim 1 wherein the capacitor bank includes a reference capacitor selectively coupled to the first selected capacitor or the second selected capacitor.

3. The shared filter apparatus according to claim 1, wherein the first direction is a receive direction and the second direction is a transmit direction.

4. The shared filter apparatus according to claim 2 further comprising a calibration circuit coupled to the configurable switch configured to measure a time constant of the reference capacitor.

5. The shared filter apparatus according to claim 4, wherein the calibration circuit selects the first selectable capacitor in response to the time constant measurement of the reference capacitor.

6. The shared filter apparatus according to claim 5, wherein the calibration circuit selects the second selectable capacitor based upon an offset value of the first selectable capacitor.

7. The shared filter apparatus according to claim 6, wherein the first selectable capacitor in combination with the reference capacitor produces a first predetermined time constant and the second selectable capacitor in combination with the reference capacitor produces a second predetermined time constant.

8. A method for a shared filter having a capacitor bank to adjust the time constant of the shared filter, comprising the steps:
selecting a first capacitor from the capacitor bank;
coupling the first capacitor to a reference capacitor to provide a first time constant;
selecting a second capacitor from the capacitor bank;
coupling the second capacitor to the reference capacitor to provide a second time constant;
receiving a first signal in a first direction using the first capacitor and the reference capacitor to produce the first time constant; and
transmitting a second signal in a second direction using the second capacitor and the reference capacitor to produce the second time constant.

9. The method for a shared filter according to claim 8 further comprising the step of determining a time constant for the reference capacitor.

10. The method for a shared filter according to claim 9 further comprising the steps of:
selecting the first capacitor from the capacitor bank in response to the time constant measurement for the reference capacitor to provide a first predetermined time constant; and
selecting the second capacitor from a predetermined offset value of the first capacitor from the capacitor bank in combination with the reference capacitor to provide a second predetermined time constant.

11. The method for a shared filter according to claim 10 further comprising the steps of:
receiving a signal using the first capacitor and the reference capacitor; and
transmitting a signal using the second capacitor and the reference capacitor.

12. The method for a shared filter according to claim 11 further comprising switching between receiving a signal using the first capacitor and the reference capacitor and transmitting a signal using the second capacitor and the reference capacitor.

13. A shared filter transceiving system having a capacitor bank to adjust the time constant of the shared filter, comprising:
a first input configured to receive a first signal;
the capacitor bank coupled to the first input having a plurality of selectable capacitors including a reference capacitor;
a second input coupled to the capacitor bank configured to receive a second signal; and
a configurable switch coupled to the capacitor bank configured to couple a first selectable capacitor with the reference capacitor when the first input is active and couple a second selectable capacitor with the reference capacitor when the second input is active.

14. The shared filter transceiving system of claim 13, wherein the first selectable capacitor and the reference capacitor provides a first predetermined time constant for the shared filter and the second selectable capacitor and the reference capacitor provides a second predetermined time constant.

15. The shared filter transceiving system of claim 13, wherein the second selectable capacitor is a predetermined offset value of the first selectable capacitor.

16. The shared filter transceiving system of claim 13, wherein the capacitor bank includes an in-phase capacitor bank and a quadrature capacitor bank.

17. The shared filter transceiving system of claim 13, wherein the first input includes:
a low noise amplifier configured to receive a radio frequency input;
in-phase and quadrature receive mixers coupled between the low noise amplifier and a first end of the in-phase and quadrature capacitor bank, respectively; and
in-phase and quadrature variable gain amplifiers coupled to a second end of the in-phase and quadrature capacitor bank, respectively.

18. The shared filter transceiving system of claim 13, wherein the second input includes:
in-phase and quadrature transmit signals coupled to a first end of the in-phase and quadrature capacitor bank, respectively;
in-phase and quadrature transmit mixers coupled to a second end of the capacitor bank; and
variable gain amplifier coupled to the in-phase and quadrature transmit mixers configured to provide a radio frequency output.
